(19) United States
(12) Patent Application Publication
(10) Pub. No.: US 2026/0082977 A1
(43) Pub. Date: Mar. 19, 2026

(54) STACKED PACKAGE STRUCTURE AND FORMING METHOD THEREOF

(71) Applicant: JCET GROUP CO., LTD., Jiangsu (CN)

(72) Inventor: Cheng Yang, Jiangsu (CN)

(73) Assignee: JCET GROUP CO., LTD., Jiangsu (CN)

(21) Appl. No.: 19/312,270

(22) Filed: Aug. 27, 2025

(30) Foreign Application Priority Data
Sep. 19, 2024 (CN) 202411308062.9

(51) Int. Cl. H10W 74/01; H10W 72/00; H10W 72/20; H10W 72/30; H10W 74/10; H10W 90/00

(52) U.S. Cl. CPC H10W 74/01; H10W 74/111; H10W 72/07236; H10W 72/07254; H10W 72/07354; H10W 72/247; H10W 72/347; H10W 72/856; H10W 72/877; H10W 90/722; H10W 90/724; H10W 90/732

(57) ABSTRACT

A stacked package structure and a forming method thereof are disclosed. The forming method includes mounting a first active surface of a first chip facing down on an upper surface of a substrate; forming a chip stacking structure on a first back surface of the first chip, including a plurality of second chips stacked sequentially in a vertical direction; performing a mass reflow process to solder the micro bumps of the upper second chip to the second connection terminals of the adjacent lower second chip; and performing a molded underfill process to form a molding layer filled between the upper and lower second chips and between the lower second chip and the first chip. This improves packaging efficiency, prevents the micro bumps from collapsing, and ensures evenness during stacking.

### CROSS-REFERENCE TO RELATED APPLICATION

This application claims the priority benefit of China application serial no. 202411308062.9, filed on Sep. 19, 2024. The entirety of the above-mentioned patent application is hereby incorporated by reference herein and made a part of this specification.

### TECHNICAL FIELD

The present disclosure relates to the field of semiconductor packaging, and in particular, to a stacked package structure and a forming method thereof.

### BACKGROUND

A high bandwidth memory (HBM) is a new type of CPU/GPU memory chip (that is, RAM), which means that a plurality of DDR chips are stacked together and then packaged with the GPU to achieve a high-capacity, high-bandwidth DDR combination array.

A conventional 3d high bandwidth memory (3D HBM) package structure uses advanced packaging techniques (such as TSV silicon through silicon via technology and micro bump technology) to vertically stack a plurality of memory chips (such as DRAM) to increase a storage capacity, and then connects the memory chips to computing unit chips (GPU/CPU/SOC Die) through a high-speed interface on an interposer.

The conventional stacking processes used in HBM manufacturing mainly include a thermal compression bonding with non-conductive film (TC-NCF) process and a mass reflow bonding with molded underfill (MR-MUF) process.

In the TC-NCF process, a layer of non-conductive film needs to be provided between every two layers of stacked memory chips during each stacking, so as to isolate an upper memory chip and a lower memory chip from each other and prevent soldering points from being impacted. This process has issues with complex manufacturing, low efficiency, and high costs.

In the MR-MUF process, during stacking of memory chips, to secure the upper and lower memory chips, the solder balls at the bottom of each layer of memory chip need to undergo a preheating bonding process first, so that the solder balls at the bottom will undergo multiple reflows. As a result, the solder balls at the bottom become unstable and may easily collapse, and during the stacking process, the upper and lower memory chips may be stacked unevenly.

### SUMMARY

The present disclosure provides a stacked package structure and a forming method thereof to improve packaging efficiency, and prevent that micro bumps on the bottom second chip are unstable and may easily collapse, so as to ensure evenness and stability of a second chip during a stacking process.

To resolve the foregoing problem, an embodiment of the present disclosure provides a stacked package structure and a forming method thereof, including:
providing a substrate, where the substrate includes an upper surface and a lower surface that are opposite to each other;
providing a first chip, where the first chip includes a first active surface and a first back surface that are opposite to each other, the first active surface has solder bumps, the first back surface has first connection terminals, the first active surface of the first chip is mounted facing down on the upper surface of the substrate, and the solder bumps are soldered to the substrate;
forming a chip stacking structure on the first back surface of the first chip, where the chip stacking structure includes a plurality of second chips stacked sequentially in a vertical direction, each second chip includes a second active surface and a second back surface that are opposite to each other, the second active surface has micro bumps, the second back surface has second connection terminals, and during sequential stacking of the plurality of second chips, the second active surface of each second chip faces down, and an upper second chip is bonded and fastened to an adjacent lower second chip through a bonding layer located between the upper second chip and the lower second chip;
performing a mass reflow bonding process to solder the micro bumps on the second active surface of the upper second chip to the second connection terminals on the second back surface of the adjacent lower second chip, and to solder the micro bumps on the second active surface of the bottom second chip to the first connection terminals on the first back surface of the first chip; and performing a molded underfill process to form a molding layer that covers the chip stacking structure and the first chip and that is filled between the upper and lower second chips, between the bottom second chip and the first chip, and between the first chip and the upper surface of the substrate.

In an optional embodiment, the bonding layer is a mechanical bonding layer that still bonds and fastens the upper and lower first chips during the mass reflow process.

In an optional embodiment, the bonding layer is made of a non-conductive adhesive or a non-conductive adhesive film; and the bonding layer is also formed between the bottom second chip and the first chip.

In an optional embodiment, the bonding layer is in a softened state or semi-softened state at a reflow temperature during the mass reflow process.

In an optional embodiment, the bonding layer is a temporary bonding layer that is completely or partially decomposed during the mass reflow process.

In an optional embodiment, the bonding layer is made of an UV adhesive or a thermally decomposable adhesive that can be decomposed at the reflow temperature during the mass reflow process; and during the mass reflow process, the bonding layer is completely decomposed.

In an optional embodiment, the reflow temperature during the mass reflow process ranges from 230° C. to 250° C.

In an optional embodiment, the bonding layer includes micro support bumps and a coating layer that covers the micro support bumps, the coating layer is made of a non-conductive adhesive or a non-conductive adhesive film, and the micro support bump is made of a metal material, organic material, or inorganic material that is not softened at the reflow temperature during the mass reflow process.

In an optional embodiment, the bonding layer includes micro support bumps and a coating layer that covers the micro support bumps, the coating layer is made of an UV adhesive or a thermally decomposable adhesive that can be decomposed at the reflow temperature during the mass reflow process, and the micro support bump is made of a metal material, organic material, or inorganic material that is not decomposed at the reflow temperature during the mass reflow process; and during the mass reflow process, the coating layer in the bonding layer is decomposed, while the micro support bumps are retained.

In an optional embodiment, during sequential stacking of the plurality of second chips, the bonding layer is pre-formed on the second back surface of the previously stacked lower second chip, or the bonding layer is pre-formed on the second active surface of the upper second chip to be stacked.

In an optional embodiment, there are a plurality of discrete bonding layers that are evenly distributed between the upper second chip and the adjacent lower second chip.

In an optional embodiment, positions of the bonding layers at different layers are the same.

In an optional embodiment, a third chip is also mounted on the upper surface of the substrate on one side of the second chip, and the third chip is electrically connected to the substrate.

Another embodiment of the present disclosure further provides a stacked package structure, including:
a substrate, where the substrate includes an upper surface and a lower surface that are opposite to each other;
a first chip, where the first chip includes a first active surface and a first back surface that are opposite to each other, the first active surface has solder bumps, the first back surface has first connection terminals, the first active surface of the first chip is mounted facing down on the upper surface of the substrate, and the solder bumps are soldered to the substrate;
a chip stacking structure located on the first back surface of the first chip, where the chip stacking structure includes a plurality of second chips stacked sequentially in a vertical direction, each second chip includes a second active surface and a second back surface that are opposite to each other, the second active surface has micro bumps, the second back surface has second connection terminals, and the second active surface of each second chip faces down, an upper second chip is bonded and fastened to an adjacent lower second chip through a bonding layer located between the upper second chip and the lower second chip, the micro bumps on the second active surface of the upper second chip in the chip stacking structure are soldered to the second connection terminals on the back surface of the adjacent second chip, and the micro bumps on the second active surface of the bottom second chip are soldered to the first connection terminals on the back surface of the first chip; and
a molding layer that covers the chip stacking structure and the first chip and that is filled between the upper and lower second chips, between the bottom second chip and the first chip between the first chip and the upper surface of the substrate.

In an optional embodiment, the bonding layer is also formed between the bottom second chip and the first chip.

In an optional embodiment, the bonding layer is a mechanical bonding layer, and the entire bonding layer is completely made of a non-conductive adhesive or a non-conductive adhesive film.

In an optional embodiment, the bonding layer includes micro support bumps and a coating layer that covers the micro support bumps, the coating layer is made of a non-conductive adhesive or a non-conductive adhesive film, and the micro support bump is made of a metal material, organic material, or inorganic material that is not softened at the reflow temperature during the mass reflow process.

In an optional embodiment, there are a plurality of discrete bonding layers that are evenly distributed between the upper second chip and the adjacent lower second chip.

In an optional embodiment, positions of the bonding layers at different layers are the same.

In an optional embodiment, the stacked package structure further includes a third chip that is mounted on the upper surface of the substrate on one side of the second chip, where the third chip is electrically connected to the substrate.

The technical solutions of the present disclosure have the following advantages:

In the present disclosure, when a plurality of layers of second chips are stacked, the upper second chip is bonded and fastened to the adjacent lower second chip through a bonding layer located between the upper second chip and the lower second chip, rather than being soldered and fastened through the micro bumps on the second active surface of the upper second chip and the second connection terminals on the back surface of the lower second chip. That is, the upper and lower second chips in the present disclosure are stacked through the bonding layer, eliminating the need for each memory chip in a conventional TC-NCF technology to require one layer of non-conductive film during stacking for bonding and isolation, thereby making the process simpler and more efficient. In addition, in the present disclosure, the upper and lower second chips are also stacked through a bonding layer, eliminating the need for the solder balls at the bottom of each layer of memory chips in the conventional MR-MUF technology to undergo a hot press bonding first during stacking, thereby preventing the micro bumps on the second chip from undergoing multiple reflows (especially reducing the number of reflows that the micro bumps on the bottom of the second chip undergo), and preventing the collapse or instability of the micro bumps on the second chip in the stacked chip structure and avoiding uneven stacking of the upper and lower second chips.

In addition, when the bonding layer is a temporary bonding layer, it will be completely or partially decomposed during mass reflow, thereby preventing or reducing the impact of the bonding layer on the flow of the material of the molding layer during the molded underfill process.

### BRIEF DESCRIPTION OF DRAWINGS

FIG. 1 to FIG. 12 are structural schematic diagrams in a forming process of a stacked package structure according to an embodiment of the present disclosure.

FIG. 13 to FIG. 22 are structural schematic diagrams in a forming process of a stacked package structure according to an embodiment of the present disclosure.

### DETAILED DESCRIPTION OF EMBODIMENTS

The following describes specific implementations of the present disclosure in detail with reference to the accompanying drawings. When embodiments of the present disclosure are described in detail, for ease of description, schematic diagrams are not partially enlarged according to a general proportion. In addition, the schematic diagrams are merely examples and should not limit the protection scope of the present disclosure. In addition, the length, width, and depth of a three-dimensional space should be included in actual manufacture.

An embodiment of the present disclosure first provides a forming method for a stacked package structure. A forming process of a stacked package structure is described in detail below with reference to the accompanying drawings.

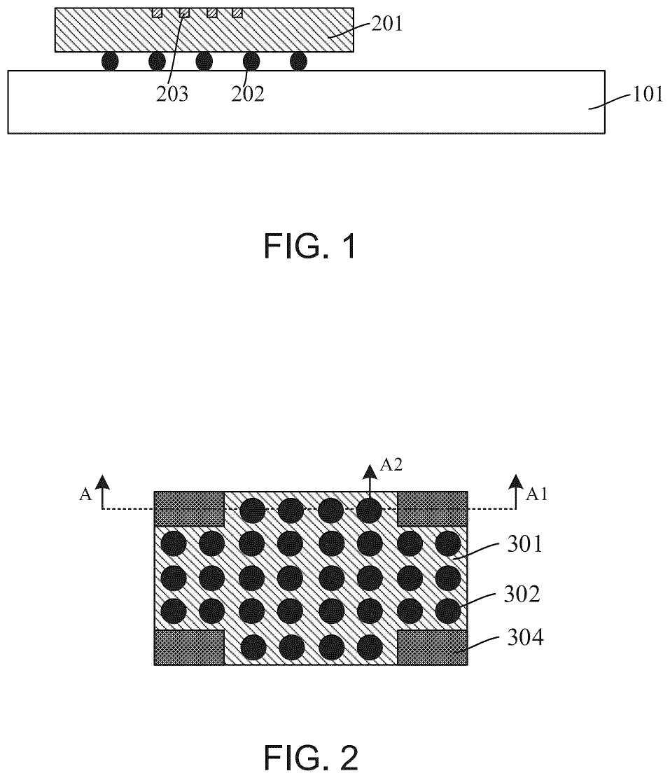

Referring to FIG. 1, a substrate 101 is provided, where the substrate 101 includes an upper surface and a lower surface that are opposite to each other; and a first chip 201 is provided, where the first chip 201 includes a first active surface and a first back surface that are opposite to each other, the first active surface has solder bumps 202, the first back surface has first connection terminals 203, the first active surface of the first chip 201 is mounted facing down on the upper surface of the substrate 101, and the solder bumps 202 are soldered to the substrate 101.

The substrate 101 serves as a support carrier and a connecting carrier during the packaging process. In an embodiment, the upper surface of the substrate 101 has a plurality of discrete first solder pads (not shown in the figure), and the lower surface of the substrate 101 has a plurality of discrete second solder pads (not shown in the figure). The substrate 101 includes connecting lines (not shown in the figure). The connecting line may include one or more of a metal layer, a connection plug, a through-silicon-via (TSV) connection, a via connection structure, or a metal conductive pillar. The connecting lines can be used for electrical connection between the first solder pads on the upper surface of the substrate 101 and the corresponding second solder pads on the lower surface of the substrate 101; the connecting lines can also be used for electrical connection between some of the first solder pads on the upper surface of the substrate 101; and the connecting lines are also used for electrical connection between some of the second solder pads on the lower surface of the substrate 101. The first solder pads on the upper surface of the substrate 101 are electrically connected to the first chip 201 mounted on the upper surface of the substrate 101 and other devices. External bumps can be subsequently formed on the second solder pads on the lower surface of the substrate, and the external bumps are used for connecting with other devices or package structures. In an embodiment, the first pads, the second pads, and the connecting line is made of metal, which may specifically be one or more of aluminum, copper, nickel, tin, titanium, tungsten, platinum, chromium, tantalum, gold, or silver. The external bump is made of tin or a tin alloy, and the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony. In an embodiment, the substrate can be one of a silicon substrate, a redistribution layer (RDL) substrate, a resin substrate, a printed circuit board (PCB), a ceramic substrate, a glass substrate, or a flexible circuit boards (FPC). In an embodiment, the substrate can be a single-layer board or a multi-layer board. In an embodiment, the substrate 101 may serve as an interposer.

The first chip 201 includes a first active surface and a first back surface that are opposite to each other. The first active surface has solder bumps 202, and the first back surface has first connection terminals 203. An integrated circuit (with specific functions) (such as a logic control circuit, not shown in the figure) is formed in the first chip 201, and the solder bumps 202 and the first connection terminals 203 are electrically connected to the integrated circuit. In an embodiment, the solder bump 202 can be a solder protrusion or can include a metal bump and a solder layer located on the top surface of the metal bump. In a specific embodiment, the first connection terminal 203 is made of one or more of aluminum, copper, titanium, nickel, tin, tungsten, platinum, chromium, tantalum, gold, or silver; the metal bump is made of one or more of aluminum, copper, titanium, nickel, tin, tungsten, platinum, chromium, tantalum, gold, or silver; and the solder bump or solder layer is made of tin or a tin alloy, where the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

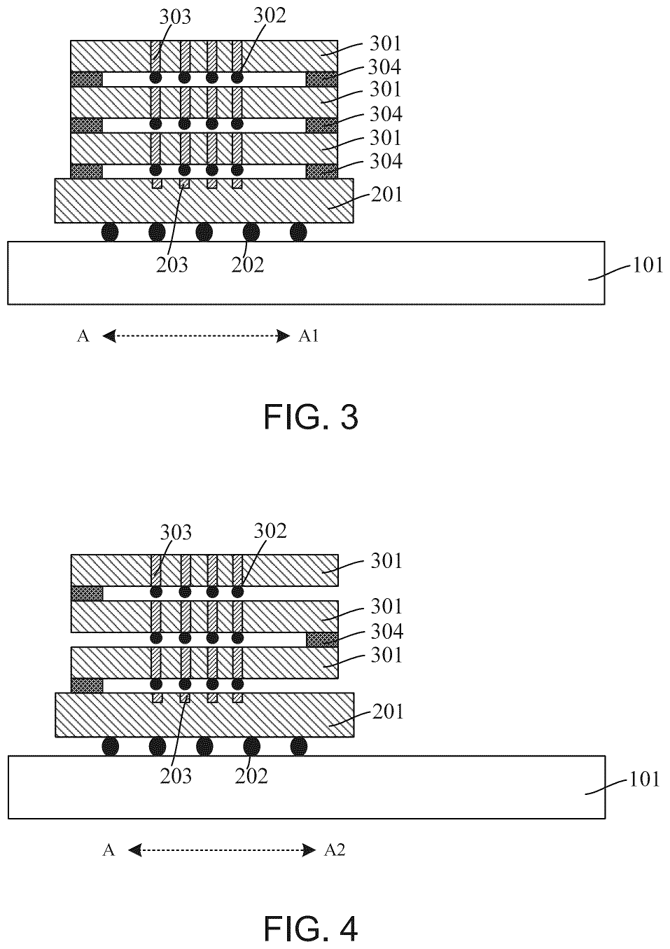

A function of the first chip 201 can be the same as or different from a function of a subsequently stacked second chip 301 (refer to FIG. 3). In an embodiment, the function of the first chip 201 can be different from the function of the subsequently stacked second chip 301, where the first chip 201 is a logic chip, the second chip 301 is a memory chip, and the logic chip is used to control and manage data storage, reading, and deletion for the memory chip. In other embodiments, the function of the first chip 201 can be the same as the function of the subsequently stacked second chip 301 (refer to FIG. 3), where both the first chip 201 and the second chip 301 are memory chips. In an embodiment, a third chip (not shown in the figure) is also mounted on the upper surface of the substrate 101 on one side of the first chip 201, where the third chip is electrically connected to the substrate 101. Specifically, the third chip can be electrically connected to the second chip 301 through some connecting lines in the substrate 101. The first chip 201 is a logic chip, the second chip 301 is a memory chip, and the third chip is a processing chip, where the processing chip can be a CPU chip or a GPU chip.

Referring to FIG. 2 to FIG. 4, FIG. 2 is a schematic structural top view of a second chip 301 stacked in FIG. 3 or FIG. 4, FIG. 3 is a cross-sectional structure of the package structure obtained along the cutting line AA1 of the second chip 301 after stacking of the second chip 301, and FIG. 4 is a cross-sectional structure of the package structure obtained along the cutting line AA2 of the second chip 301 after stacking of the second chip 301. A chip stacking structure is formed on the first back surface of the first chip 201, and the chip stacking structure includes a plurality of second chips 301 stacked sequentially in the vertical direction. Each second chip 301 includes a second active surface and a second back surface that are opposite to each other, where the second active surface has micro bumps 302, and the second back surface has second connection terminals 303. During sequential stacking of the plurality of second chips 301, the second active surface of each second chip 301 faces down, and the upper second chip 301 is bonded and fastened to the adjacent lower second chip 301 through a bonding layer 304 located between the upper second chip 301 and the lower second chip 301.

The second active surface of the second chip 301 has micro bumps 302, and the second back surface of the second chip 301 has second connection terminals 303, where the micro bump 302 is a micro solder ball, and the second connection terminal 303 includes a Through Silicon Via (TSV) interconnection structure. A specific functional integrated circuit (such as data storage and reading circuit, which are not shown in the figure) is formed in the second chip 301, where the second connection terminals 303 and micro bumps 302 are electrically connected to the integrated circuit. In a specific embodiment, the second connection terminal 303 is made of one or more of aluminum, copper, titanium, nickel, tin, tungsten, platinum, chromium, tantalum, gold, or silver; the micro bump 302 is made of one or more of aluminum, copper, titanium, nickel, tin, tungsten, platinum, chromium, tantalum, gold, or silver; and the solder bump or solder layer is made of tin or a tin alloy, where the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

In an embodiment, the second chip 301 is a memory chip, where the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)).

When a plurality of second chips 301 are stacked sequentially, the second active surface of each second chip 301 faces down; and the upper second chip 301 is bonded and fastened to the adjacent lower second chip 301 through a bonding layer 304 located between the upper second chip 301 and the lower second chip 301, rather than being fastened through soldering between the micro bumps 302 on the second active surface of the upper second chip 301 and the second connection terminals 303 on the second back surface of the adjacent lower second chip 301. Specifically, when the upper second chip 301 is bonded and fastened to the lower second chip 301 through the bonding layer 304, the micro bumps 302 on the active surface of the upper second chip 301 are not in contact with the second connection terminals 303 on the back surface of the adjacent lower second chip 301 (or the micro bumps 302 on the second active surface of the upper second chip 301 are suspended above the back surface of the lower second chip 301); or the micro bumps 302 may be in slight contact with the second connection terminals 303 on the back surface of the adjacent lower second chip 301, but there is no bonding or soldering connection between the micro bumps 302 and the second connection terminals 303. That is, the upper and lower second chips 301 in the present disclosure are stacked through the bonding layer 304, eliminating the need for each memory chip in a conventional TC-NCF technology to require one layer of non-conductive film during stacking for bonding and isolation, thereby making the process simpler and more efficient. In addition, in the present disclosure, the upper and lower second chips 301 are also stacked through a bonding layer 304, eliminating the need for the solder balls at the bottom of each layer of memory chips in the conventional MR-MUF technology to undergo a hot press bonding first during stacking, thereby preventing the micro bumps 302 on the second chip 301 from undergoing multiple reflows (especially reducing the number of reflows that the micro bumps 302 on the bottom of the second chip 301 undergo), and preventing the collapse or instability of the micro bumps 302 on the second chip 301 in the stacked chip structure and avoiding uneven stacking of the upper and lower second chips 301.

In an embodiment, the bonding layer 304 is also formed between the bottom second chip 301 and the first chip 201. In an embodiment, a thickness of the bonding layer 304 is equal to or greater than (slightly greater than) a thickness of the micro bump 302.

The bonding layer 304 can be a temporary bonding layer or a mechanical bonding layer. The temporary bonding layer will be completely or partially decomposed during the subsequent mass reflow process. The mechanical bonding layer cannot be decomposed at a high temperature; the mechanical bonding layer can be in a softened state or semi-softened state at the reflow temperature during the subsequent mass reflow process, to still provide support for the upper second chip.

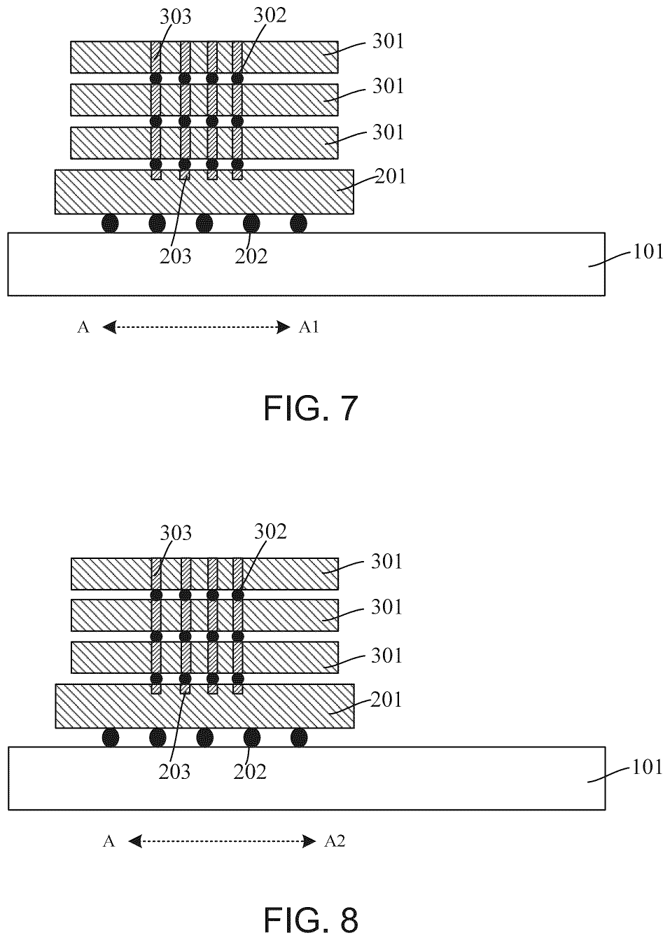

In an embodiment, the bonding layer 304 is a temporary bonding layer, where the temporary bonding layer is made of an UV adhesive or a thermally decomposable adhesive that can be decomposed at the reflow temperature during the subsequent mass reflow process; the temporary bonding layer is completely made up of UV adhesive or a thermally curable adhesive that can be decomposed at the reflow temperature during the mass reflow process, and when the mass reflow process is conducted subsequently, the temporary bonding layer is completely decomposed. The temporary bonding layer is used for bonding and fastening between the upper and lower second chips 301 during stacking of the second chips 301, to prevent movement or offset between the second chips 301, so as to ensure evenness of the stacked upper and lower second chips 301. The temporary bonding layer is not decomposed during the initial heating stage of the mass reflow process, to still provide support for the upper and lower second chips 301, so as to ensure the mechanical stability and evenness of the chip stacking structure during the mass reflow process, thereby improving the accuracy of soldering between the micro bumps 302 of the upper second chip 301 and the second connection terminals 203 of the lower second chip 301 during the mass reflow process, and effectively prevent deformation or short-circuiting between the micro bumps 302 on the lower second chip 301 caused by excessive pressure. In addition, during the subsequent mass reflow process, the micro bumps 302 on the second active surface of the upper second chip 301 in the chip stacking structure are soldered to the second connection terminals 303 on the second back surface of the adjacent lower second chip 301, and the micro bumps 302 on the second active surface of the lower second chip 301 are soldered to the first connection terminals 203 on the first back surface of the first chip 201 (refer to FIG. 7 and FIG. 8). This makes it easy for the bonding layer 304 to be completely decomposed during the mass reflow process, thereby preventing or reducing the impact of the presence of the bonding layer 304 on the flow of the material of the molding layer during the subsequent molded underfill process.

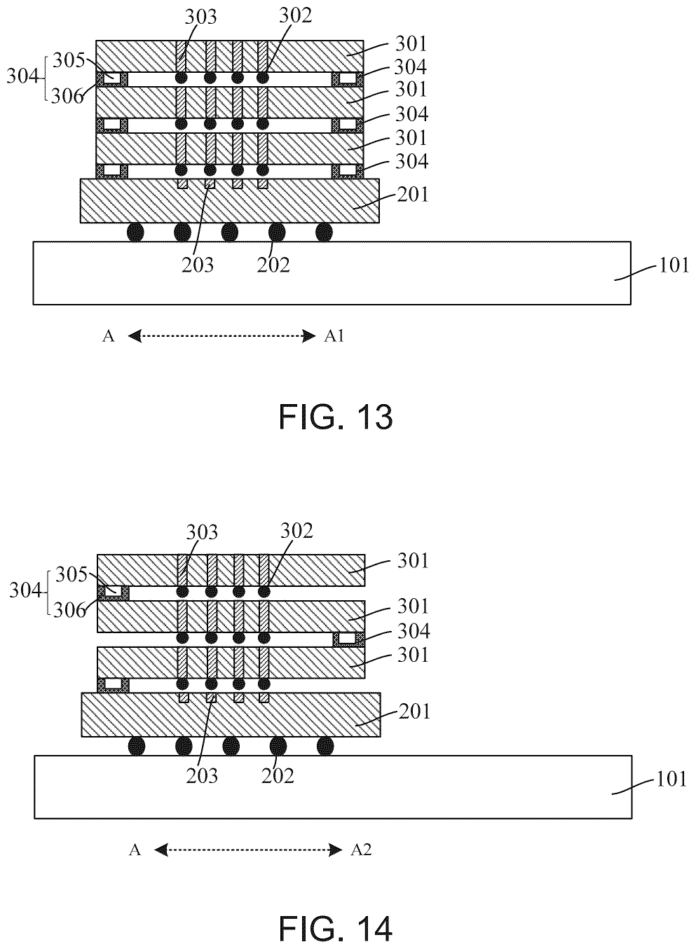

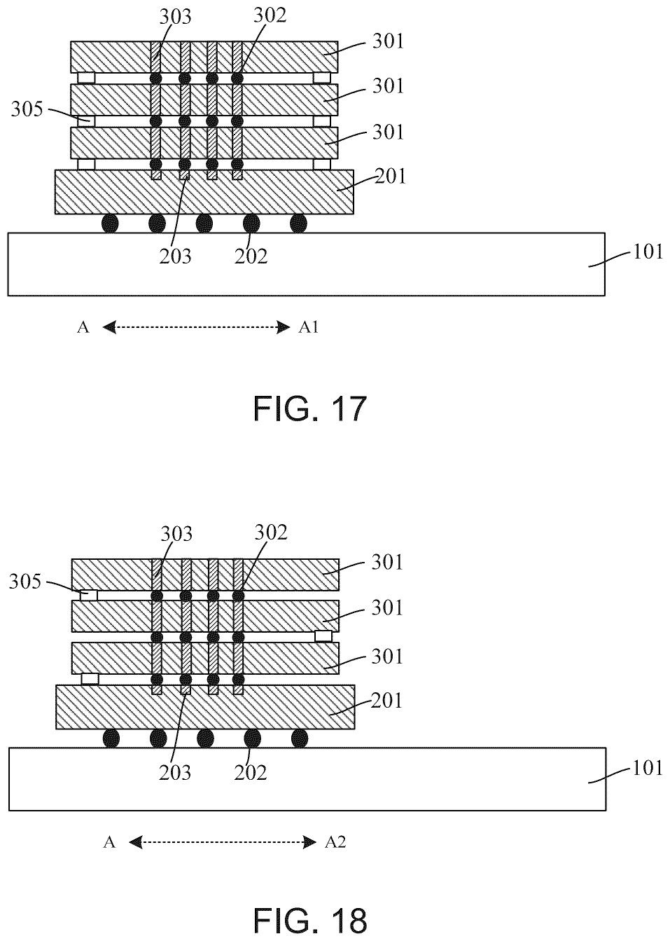

In another embodiment, referring to FIG. 13 and FIG. 14, the temporary bonding layer (the bonding layer 304) includes micro support bumps 305 and a coating layer 306 that covers the micro support bumps 305. The coating layer 306 is made of an UV adhesive or a thermally curable adhesive that can be decomposed at the reflow temperature during the mass reflow process, and the micro support bump 305 is made of a metal material, organic material, or inorganic material that is not decomposed at the reflow temperature during the mass reflow process. During the subsequent mass reflow process, the coating layer 306 in the temporary bonding layer is decomposed, and the micro support bumps 305 are retained (refer to FIG. 17 and FIG. 18). The molding layer 306 is used to bond and fasten the second chip 301 between the upper and lower layers during chip stacking. In the subsequent mass reflow process, the molding layer 306 is decomposed at the reflow temperature, while the micro support bumps 305 are not decomposed at the reflow temperature during the mass reflow process and are retained between the upper and lower second chips 301 to support the upper second chip 301. This better ensures the mechanical stability and evenness of the chip stacking structure, preventing the structure from tilting or becoming uneven during the mass reflow process, thereby further improving the accuracy of soldering between the micro bumps 302 of the upper second chip 301 and the second connection terminals 203 of the lower second chip 301. This also effectively prevents deformation or short-circuiting between the micro bumps 302 on the lower second chip 301 caused by excessive pressure.

In an embodiment, the process for forming the temporary bonding layer includes a dispensing process (or printing process) and a curing process. The dispensing process (or printing process) is used to apply (or print) an UV adhesive or a thermally curable adhesive on the second active surface or the second back surface of the second chip 301, and the curing process is used to cure the applied (or printed) UV adhesive or thermally curable adhesive.

In an embodiment, when the temporary bonding layer is made of an UV adhesive, the temporary bonding layer is cured by UV light during the stacking process; or when the temporary bonding layer is a thermally decomposable adhesive, the temporary bonding layer is cured through thermal reflow during the stacking process. In an embodiment, the plurality of second chips 301 are stacked by a bonding device, where the bonding device includes a thermal compression bonding (TCB) device or a laser compression bonding (LCB) device.

In an embodiment, a thickness of the temporary bonding layer is equal to or greater than (slightly greater than) a thickness of the micro bump 302.

In an embodiment, the bonding layer 304 is a mechanical bonding layer, and the mechanical bonding layer is made of a non-conductive adhesive or a non-conductive adhesive film. The mechanical bonding layer can be used for bonding and fastening between the upper and lower second chips 301 during stacking of the second chips 301. In addition, during the subsequent mass reflow process, the mechanical bonding layer is not decomposed at a high temperature; instead, the mechanical bonding layer remains in a softened or semi-softened state, continuing to provide support for the upper second chip 301. This enhances the evenness and mechanical stability of the chip stacking structure during the mass reflow process, and prevents tilting or unevenness during the mass reflow process, thereby improving the accuracy of soldering between the micro bumps 302 of the upper second chip 301 and the second connection terminals 203 of the lower second chip 301, and preventing deformation or short-circuiting between the micro bumps 302 on the lower second chip 301 caused by excessive pressure.

In an embodiment, the mechanical bonding layer made of the non-conductive adhesive or non-conductive adhesive film can be in a softened or semi-softened state at the reflow temperature during the subsequent mass reflow process. The reflow temperature during the mass reflow process ranges from 230° C. to 250° C.

In an optional embodiment, the mechanical bonding layer is completely made of a non-conductive adhesive or a non-conductive adhesive film.

In another embodiment, referring to FIG. 13 and FIG. 14, the mechanical bonding layer (the bonding layer 304) includes micro support bumps 305 and a coating layer 306 that covers the micro support bumps 305. The coating layer 306 is made of a non-conductive adhesive or a non-conductive adhesive film, and the micro support bump 305 is made of a metal material, organic material, or inorganic material that is not softened at the reflow temperature during mass reflow processes. The metal material is one or more of aluminum, copper, titanium, nickel, tin, tungsten, platinum, chromium, tantalum, gold, or silver; and the organic material is a polymer or a resin; and the inorganic material is one or more of silicon oxide, silicon nitride, silicon oxynitride, carbon silicon oxide, or carbon silicon nitride. The process of forming the mechanical bonding layer includes first forming the micro support bumps 305 on the second back surface or second active surface of the second chip 301, and then forming the coating layer 306 that covers the micro support bumps 305. The micro support bumps 305 can be formed during the front-end integrated manufacturing process when the second chip 301 is created. That is, the micro support bumps 305 is formed on the second back surface or second active surface of each second chip on a wafer before a plurality of second chips 301 are cut from the wafer. The coating layer 306 is used for bonding and fastening between the upper and lower second chips 301 during the chip stacking. During the subsequent mass reflow process, the coating layer 306 is softened or semi-softened at the reflow temperature, while the micro support bumps 305 are not softened at the reflow temperature, thereby better and more stably supporting the upper second chip 301. This ensures better mechanical stability and evenness of the chip stacking structure, preventing the chip stacking structure from tilting or becoming uneven during the mass reflow process, thereby further improving the accuracy of soldering between the micro bumps 302 of the upper second chip 301 and the second terminal 203 of the lower second chip 301 during the mass reflow process. This also effectively prevents deformation or short-circuiting between the micro bumps 302 on the lower second chip 301 caused by excessive pressure.

Still referring to FIG. 3 and FIG. 4, in an embodiment, during sequential stacking of the plurality of second chips 301, the bonding layer 304 can be pre-formed on the second back surface of the lower stacked second chip 301, or the bonding layer 304 can be pre-formed on the second active surface of the upper second chip 301 to be stacked.

There are a plurality of discrete bonding layers 304 between the upper and lower second chips 301. In an embodiment, the plurality of discrete bonding layers 304 are evenly distributed between the upper second chip 301 and the adjacent lower second chip 301 to stably support and fasten the upper second chip 301. In an embodiment, the positions of the bonding layers 304 at different layers are the same, to simplify the stacking process while ensuring the stability and evenness during the stacking process. In a specific embodiment, the plurality of discrete bonding layers 304 are evenly distributed in a plurality of positions close to the edges between the upper second chip 301 and the adjacent lower second chip 301, or may be in other optimized positions.

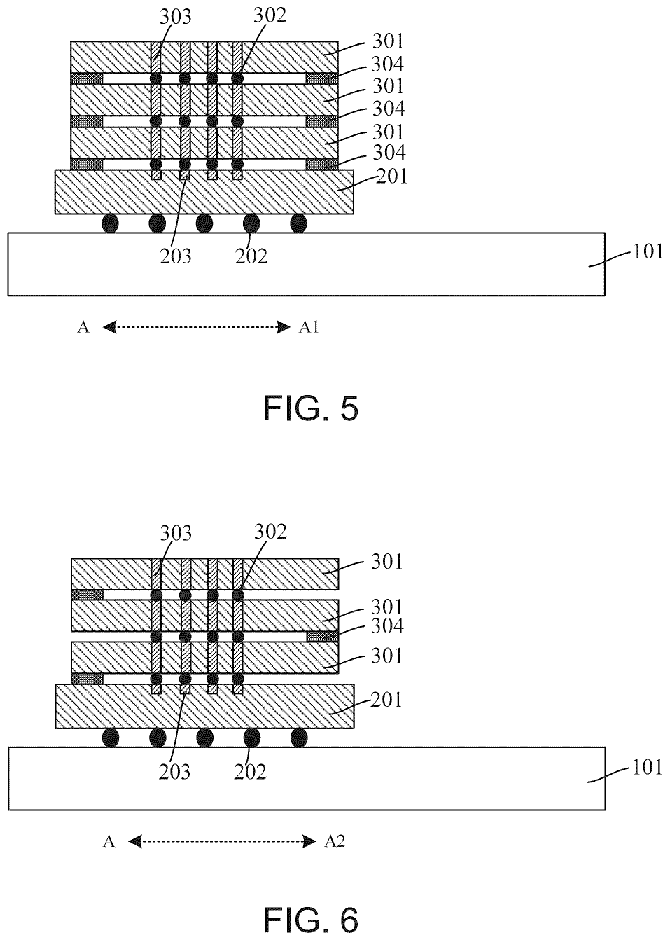

Referring to FIG. 5 and FIG. 6, during the mass reflow (MR) bonding process, the micro bumps 302 on the active surface of the upper second chip 301 in the chip stacking structure are bonded to the second connection terminal 303 on the back surface of the adjacent lower second chip 301, and the micro bumps 302 on the active surface of the lower second chip 301 are soldered to the first connection terminal 203 on the back surface of the first chip 201.

A purpose of the mass reflow process is to achieve a one-time mass soldering of all micro bumps 302 between the upper and lower second chips 302 in the chip stacking structure to the corresponding first connection terminals 203, thereby improving manufacturing efficiency.

In an embodiment, the mass reflow process essentially includes an initial temperature increase stage, a reflow stage, and a cooling stage. The reflow temperature during the reflow stage is the highest temperature during the mass reflow process. In an embodiment, the reflow temperature during the mass reflow process ranges from 230° C. to 250° C.

In an embodiment, still referring to FIG. 5 and FIG. 6, when the bonding layer 304 is a mechanical bonding layer and the mechanical bonding layer is completely made of a non-conductive adhesive or a non-conductive adhesive film, the bonding layer 304 are not softened or are only partially softened during the initial heating stage of the mass reflow process. During the reflow stage of the mass reflow process, the bonding layer 304 is in a softened state or semi-softened state. That is, during the mass reflow process, the bonding layer 304 can still effectively bond and support the upper and lower second chips 301, thereby ensuring the mechanical stability and evenness of the chip stacking structure during the mass reflow process.

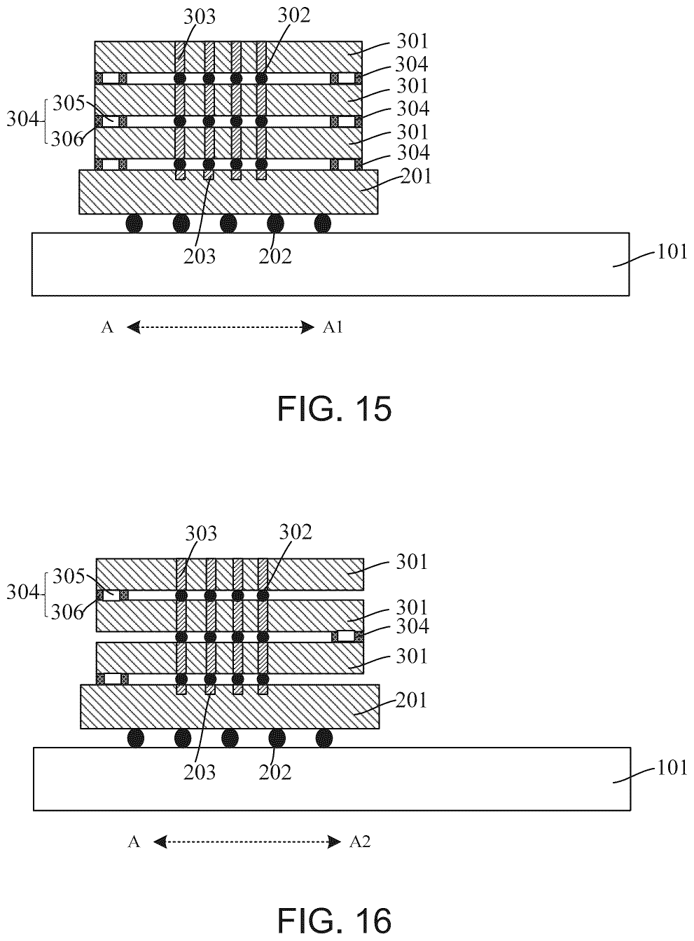

In another embodiment, referring to FIG. 15 and FIG. 16, when the bonding layer 304 is a mechanical bonding layer, the mechanical bonding layer includes micro support bumps 305 and a coating layer 306 that covers the micro support bumps 305, the coating layer 306 is made of a non-conductive adhesive or a non-conductive adhesive film, the micro support bump 305 is made of a metal material, organic material, or inorganic material that is not softened at the reflow temperature during the mass reflow process, during the mass reflow process, the coating layer 306 is softened or partially softened at the reflow temperature, while the micro support bumps 305 are not softened at the reflow temperature during the mass reflow process.

In another embodiment, referring to FIG. 7 and FIG. 8, when the bonding layer 304 is a temporary bonding layer, and the temporary bonding layer is completely made of an UV adhesive or a thermally curable adhesive that can be decomposed at the reflow temperature during the mass reflow process, the bonding layer 304 cannot be decomposed during the initial heating stage of the mass reflow process, thereby providing support for the upper and lower second chip 301, and ensuring the mechanical stability and evenness of the chip stacking structure during the mass reflow process. This improves the accuracy of soldering between the micro bumps 302 of the upper second chip 301 and the second connection terminals 203 of the lower second chip 301, and effectively prevents deformation or short-circuiting caused by excessive pressure between the micro bumps 302 on the lower second chip 301. The bonding layer 304 is completely decomposed during the reflow stage of the mass reflow process.

In another embodiment, referring to FIG. 17 and FIG. 18, when the bonding layer 304 is a temporary bonding layer and the temporary bonding layer includes micro support bumps 305 and a coating layer 306 that covers the micro support bumps 305, the coating layer 306 is made of an UV adhesive or a thermally curable adhesive that can be decomposed at the reflow temperature during the mass reflow process, and the micro support bump 305 is made of a metal material, organic material, or inorganic material that is not decomposed at the reflow temperature during the mass reflow process; and during the mass reflow process, the coating layer 306 in the temporary bonding layer is decomposed, while the micro support bumps 305 are retained.

In an embodiment, a certain pressure 11 is applied to the second back surface of the second chip 301 at the topmost layer during the mass reflow process. The applied pressure 11 can gradually decrease or be eliminated during the latter half of the mass reflow process.

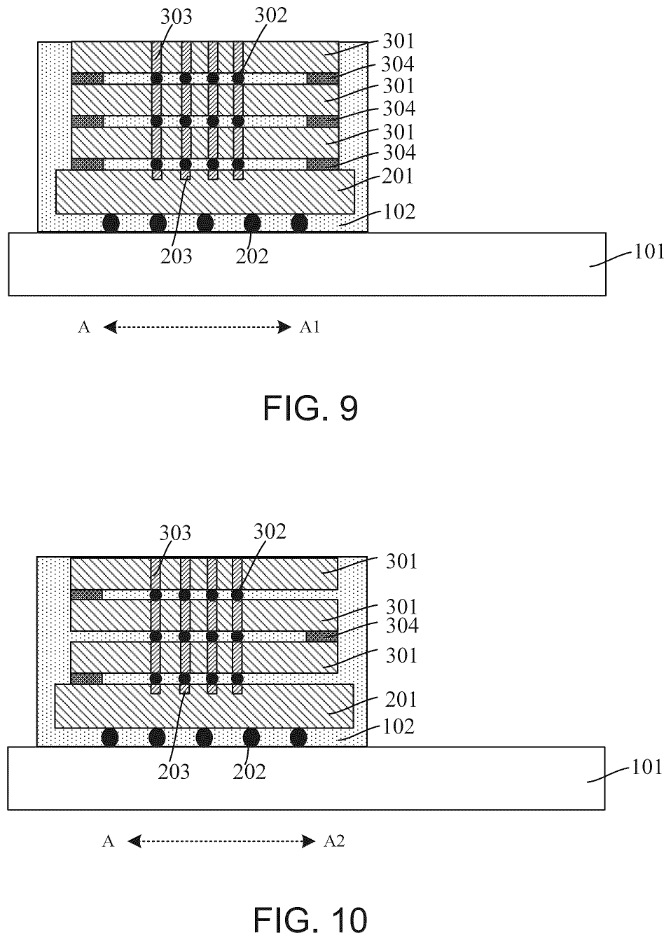

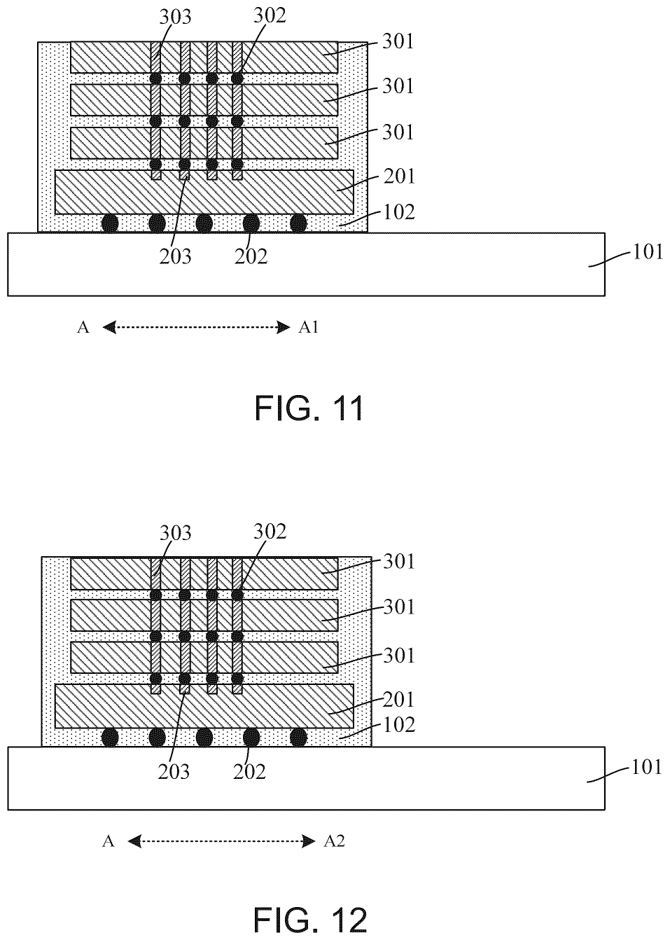

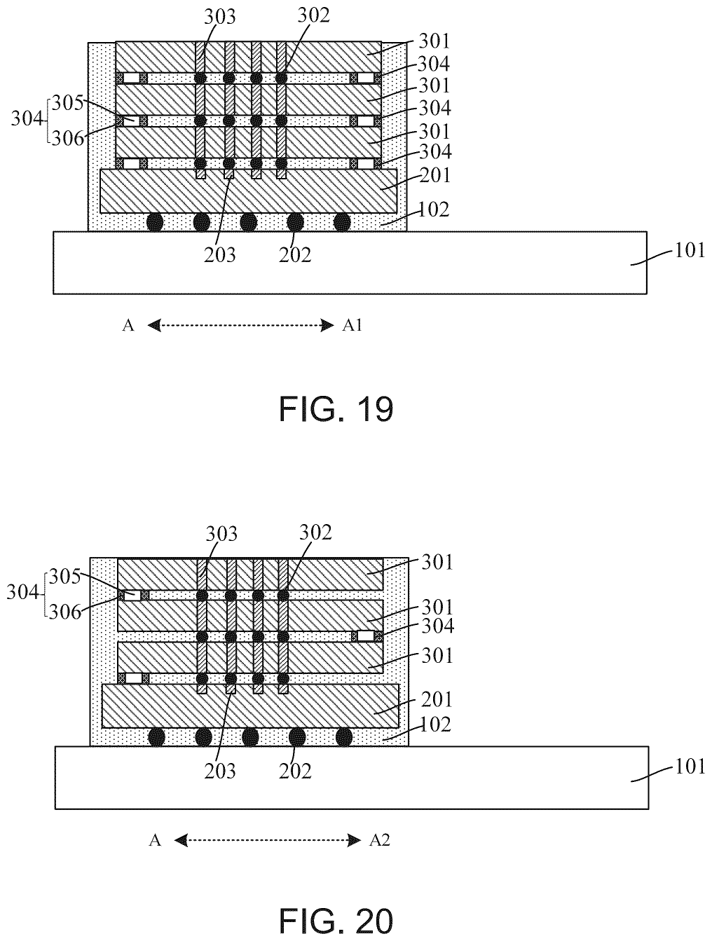

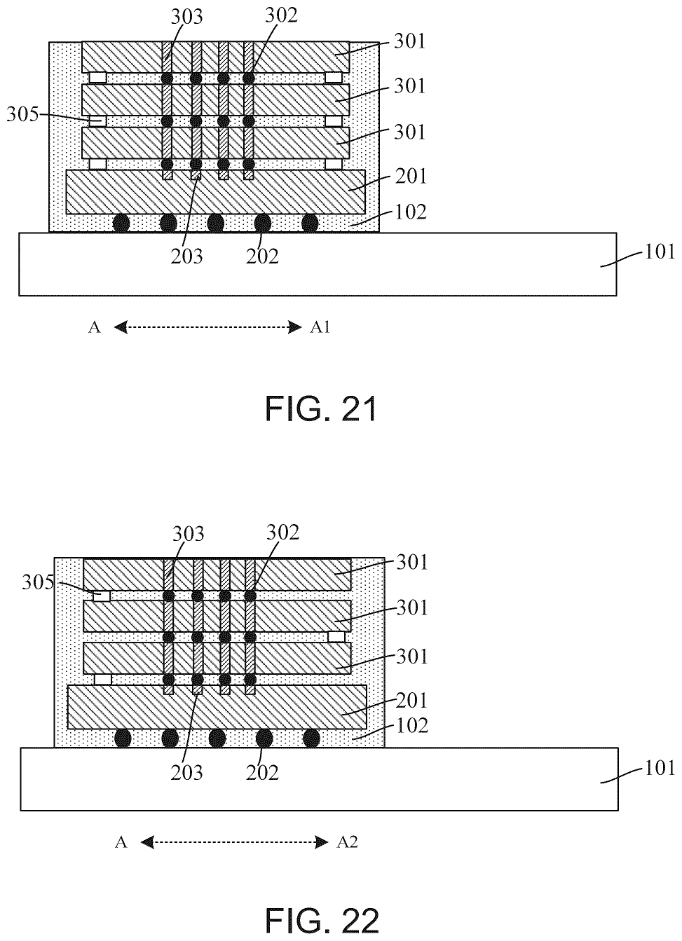

Referring to FIG. 9 and FIG. 10, or referring to FIG. 11 and FIG. 12, or referring to FIG. 19 and FIG. 20, or referring to FIG. 21 and FIG. 22, the Molded Underfill (MUF) process is performed to form a molding layer 102 that covers the chip stacking structure and the first chip 201 and that is filled between the upper and lower second chips 301, between the bottom second chip 301 and the first chip 201, and between the first chip 201 and the upper surface of the substrate 101.

In an embodiment, the molding layer 102 is made of Liquid epoxy Molding Compound (LMC). In other embodiments, the molding layer 102 can also be made of other liquid resin molding compounds, such as liquid polyimide resin molding compound, liquid cyclopentene resin molding compound, or liquid polybenzimidazole resin molding compound.

In an embodiment, the reflow curing temperature during forming of the molding layer 102 ranges from 160° C. to 180° C.

In an embodiment, the molding layer 102 may cover or expose the second back surface of the second chip 301 at the top layer.

Another embodiment of the present disclosure further provides a stacked package structure. Referring to FIG. 9 and FIG. 10, the stacked package structure includes:
a substrate 101, where the substrate 101 includes an upper surface and a lower surface that are opposite to each other;
a first chip 201, where the first chip 201 includes a first active surface and a first back surface that are opposite to each other, the first active surface has solder bumps 202, the first back surface has first connection terminals 203, the first active surface of the first chip 201 is mounted facing down on the upper surface of the substrate 101, and the solder bumps 202 are soldered to the substrate 101;
a chip stacking structure located on the first back surface of the first chip 201, where the chip stacking structure includes a plurality of second chips 301 stacked sequentially in a vertical direction, each second chip 301 includes a second active surface and a second back surface that are opposite to each other, the second active surface has micro bumps 302, the second back surface has second connection terminals 303, and the second active surface of each second chip 301 faces down, an upper second chip 301 is bonded and fastened to an adjacent lower second chip 301 through a bonding layer 304 located between the upper second chip 301 and the lower second chip 301, the micro bumps 302 on the second active surface of the upper second chip 301 in the chip stacking structure are soldered to the second connection terminals 303 on the back surface of the adjacent second chip 301, and the micro bumps 302 on the second active surface of the bottom second chip 301 are soldered to the first connection terminals 203 on the back surface of the first chip 201; and
a molding layer 102 that covers the chip stacking structure and the first chip 201 and that is filled between the upper and lower second chips 301, between the bottom second chip 301 and the first chip 201, and between the first chip 201 and the upper surface of the substrate 101.

In an embodiment, the bonding layer 304 is also formed between the bottom second chip 301 and the first chip 201.

In an embodiment, the bonding layer 304 is a mechanical bonding layer, and the bonding layer 304 is completely made of a non-conductive adhesive or a non-conductive adhesive film. The non-conductive adhesive or non-conductive adhesive film cannot be decomposed at the reflow temperature during the mass reflow process. In an embodiment, the reflow temperature during the mass reflow process ranges from 230° C. to 250° C.

In another embodiment, referring to FIG. 19 and FIG. 20, the bonding layer 304 includes micro support bumps 305 and a coating layer 306 that covers the micro support bumps 305, where the coating layer 306 is made of a non-conductive adhesive or a non-conductive adhesive film, and the micro support bump 305 is made of a metal material, organic material, or inorganic material that cannot be decomposed at the reflow temperature during the mass reflow process.

In an embodiment, there are a plurality of discrete bonding layer 304, which are evenly distributed between the upper second chip 301 and the adjacent lower second chip 301. Positions of the bonding layers 304 at different layers are the same.

In an embodiment, the stacked package structure further includes a third chip (not shown in the figure) mounted on the upper surface of the substrate 101 on one side of the first chip 201, where the third chip is electrically connected to the substrate.

In an embodiment, the first chip 201 is a logic chip, the second chip 301 is a memory chip, and the third chip is a processing chip.

The present disclosure has been described with reference to the preferred embodiments, which are not used to limit the present disclosure. Those skilled in the art can make possible variations and modifications to the present disclosure using the disclosed methods and technical contents without departing from the spirit and scope of the present disclosure; and therefore, any simple modifications, equivalent changes and modifications made to the foregoing embodiments according to the technical spirit of the present disclosure without departing from the content of the technical solutions of the present disclosure shall fall within the protection scope of the technical solutions of the present disclosure.

What is claimed is:

1. A forming method for a stacked package structure, comprising:
providing a substrate, wherein the substrate comprises an upper surface and a lower surface that are opposite to each other;
providing a first chip, wherein the first chip comprises a first active surface and a first back surface that are opposite to each other, the first active surface has solder bumps, the first back surface has first connection terminals, the first active surface of the first chip is mounted facing down on the upper surface of the substrate, and the solder bumps are soldered to the substrate;
forming a chip stacking structure on the first back surface of the first chip, wherein the chip stacking structure comprises a plurality of second chips stacked sequentially in a vertical direction, each second chip comprises a second active surface and a second back surface that are opposite to each other, the second active surface has micro bumps, the second back surface has second connection terminals, and during sequential stacking of the plurality of second chips, the second active surface of each second chip faces down, and an upper second chip is bonded and fastened to an adjacent lower second chip through a bonding layer located between the upper second chip and the lower second chip;
performing a mass reflow bonding process to solder the micro bumps on the second active surface of the upper second chip to the second connection terminals on the second back surface of the adjacent lower second chip, and to solder the micro bumps on the second active surface of a bottom second chip to the first connection terminals on the first back surface of the first chip; and
performing a molded underfill process to form a molding layer that covers the chip stacking structure and the first chip and that is filled between the upper and lower second chips, between the bottom second chip and the first chip, and between the first chip and the upper surface of the substrate.

2. The forming method for the stacked package structure according to claim 1, wherein the bonding layer is a mechanical bonding layer that still bonds and fastens the upper and lower first chips during a mass reflow process.

3. The forming method for the stacked package structure according to claim 2, wherein the bonding layer is made of a non-conductive adhesive or a non-conductive adhesive film; and the bonding layer is also formed between the bottom second chip and the first chip.

4. The forming method for the stacked package structure according to claim 2, wherein the bonding layer is in a softened state or semi-softened state at a reflow temperature during the mass reflow process.

5. The forming method for the stacked package structure according to claim 4, wherein the bonding layer is a temporary bonding layer that is completely or partially decomposed during the mass reflow process.

6. The forming method for the stacked package structure according to claim 5, wherein the bonding layer is made of an UV adhesive or a thermally decomposable adhesive that can be decomposed at the reflow temperature during the mass reflow process; and during the mass reflow process, the bonding layer is completely decomposed.

7. The forming method for the stacked package structure according to claim 4, wherein the reflow temperature during the mass reflow process ranges from 230°C to 250°C.

8. The forming method for the stacked package structure according to claim 4, wherein the bonding layer comprises micro support bumps and a coating layer that covers the micro support bumps, the coating layer is made of a non-conductive adhesive or a non-conductive adhesive film, and the micro support bump is made of a metal material, organic material, or inorganic material that is not softened at the reflow temperature during the mass reflow process.

9. The forming method for the stacked package structure according to claim 5, wherein the bonding layer comprises micro support bumps and a coating layer that covers the micro support bumps, the coating layer is made of an UV adhesive or a thermally decomposable adhesive that can be decomposed at the reflow temperature during the mass reflow process, and the micro support bump is made of a metal material, organic material, or inorganic material that is not decomposed at the reflow temperature during the mass reflow process; and
during the mass reflow process, the coating layer in the bonding layer is decomposed, while the micro support bumps are retained.

10. The forming method for the stacked package structure according to claim 1, wherein during sequential stacking of the plurality of second chips, the bonding layer is pre-formed on the second back surface of the previously stacked lower second chip, or the bonding layer is pre-formed on the second active surface of the upper second chip to be stacked.

11. The forming method for the stacked package structure according to claim 1, wherein there are a plurality of discrete bonding layers that are evenly distributed between the upper second chip and the adjacent lower second chip.

12. The forming method for the stacked package structure according to claim 11, wherein positions of the bonding layers at different layers are the same.

13. The forming method for the stacked package structure according to claim 1, wherein a third chip is also mounted on the upper surface of the substrate on one side of the second chip, and the third chip is electrically connected to the substrate.

14. A stacked package structure, comprising:
a substrate, wherein the substrate comprises an upper surface and a lower surface that are opposite to each other;
a first chip, wherein the first chip comprises a first active surface and a first back surface that are opposite to each other, the first active surface has solder bumps, the first back surface has first connection terminals, the first active surface of the first chip is mounted facing down on the upper surface of the substrate, and the solder bumps are soldered to the substrate;
a chip stacking structure located on the first back surface of the first chip, wherein the chip stacking structure comprises a plurality of second chips stacked sequentially in a vertical direction, each second chip comprises a second active surface and a second back surface that are opposite to each other, the second active surface has micro bumps, the second back surface has second connection terminals, and the second active surface of each second chip faces down, an upper second chip is bonded and fastened to an adjacent lower second chip through a bonding layer located between the upper second chip and the lower second chip, the micro bumps on the second active surface of the upper second chip in the chip stacking structure are soldered to the second connection terminals on the back surface of the adjacent second chip, and the micro bumps on the second active surface of a bottom second chip are soldered to the first connection terminals on the back surface of the first chip; and
a molding layer that covers the chip stacking structure and the first chip and that is filled between the upper and lower second chips, between the bottom second chip and the first chip between the first chip and the upper surface of the substrate.

15. The stacked package structure according to claim 14, wherein the bonding layer is also formed between the bottom second chip and the first chip.

16. The stacked package structure according to claim 14, wherein the bonding layer is a mechanical bonding layer, and the entire bonding layer is completely made of a non-conductive adhesive or a non-conductive adhesive film.

17. The stacked package structure according to claim 14, wherein the bonding layer comprises micro support bumps and a coating layer that covers the micro support bumps, the coating layer is made of a non-conductive adhesive or a non-conductive adhesive film, and the micro support bump is made of a metal material, organic material, or inorganic material that is not softened at a reflow temperature during a mass reflow process.

18. The stacked package structure according to claim 14, wherein there are a plurality of discrete bonding layers that are evenly distributed between the upper second chip and the adjacent lower second chip.

19. The stacked package structure according to claim 18, wherein positions of the bonding layers at different layers are the same.

20. The stacked package structure according to claim 14, further comprising: a third chip that is mounted on the upper surface of the substrate on one side of the second chip, wherein the third chip is electrically connected to the substrate.
